(19) United States
(12) Patent Application Publication
(10) Pub. No.: US 2025/0058417 A1
(43) Pub. Date: Feb. 20, 2025

(54) ELECTROSTATIC DISCHARGE SYSTEM FOR A POWER TOOL

(71) Applicant: MILWAUKEE ELECTRIC TOOL CORPORATION, Brookfield, WI (US)

(72) Inventors: Brennan O’Gorman, West Bend, WI (US); Jesse A. Gibb, Milwaukee, WI (US)

(21) Appl. No.: 18/805,277

(22) Filed: Aug. 14, 2024

Related U.S. Application Data
(60) Provisional application No. 63/519,720, filed on Aug. 15, 2023.

(51) Int. Cl. B23Q 11/00

(52) U.S. Cl. CPC B23Q 11/0046; B23Q 11/0071

(57) ABSTRACT

A power tool includes a housing, a motor disposed in the housing, and a transfer tube at least partially disposed within the housing, and a printed circuit board. A fan is driven by the motor to cause dust to move along the transfer tube. A static discharge mechanism extends from an interior of the housing to an exterior of the housing and is configured to dissipate electrostatic charge from the printed circuit board.

### CROSS-REFERENCE TO RELATED APPLICATIONS

This application claims priority to and incorporates by reference U.S. Provisional Patent Application No. 63/519,720, filed Aug. 15, 2023.

### FIELD OF THE INVENTION

The present disclosure relates to power tools, and more particularly, to dust collection assemblies for use with power tools.

### BACKGROUND OF THE INVENTION

Dust collection assemblies are typically used in tandem with hand-held drilling tools, such as rotary hammers, to collect dust and other debris during a drilling operation preventing dust and other debris from accumulating at a worksite. Such dust collection assemblies may be attached to a rotary hammer to position a suction inlet of the collector proximate a drill bit attached to the rotary hammer. Such dust collection assemblies may also include an on-board dust container in which dust and other debris is accumulated. Such dust containers are often removable from the dust collection assembly to facilitate disposal of the accumulated dust and debris.

### SUMMARY OF THE INVENTION

In one aspect, the disclosure provides a power tool comprising a housing including a handle and a drive unit housing, a motor disposed within the drive unit housing, an output chuck configured to receive a tool bit driven by the motor for performing a working operation, a transfer tube at least partially disposed within the housing, a fan driven by the motor to induce an airflow for transporting dust and debris generated during the working operation through the transfer tube, thereby creating a static charge on the transfer tube, and a conductor disposed at least partially exposed along an exterior side of the housing to transmit the static charge that is generated during the working operation.

In one aspect, the disclosure provides a power tool comprising a housing including a first housing and a second housing, a motor disposed within the second housing, an output portion configured to receive a tool bit driven by the motor for performing a working operation, a transfer tube at least partially disposed within the housing, a fan driven by the motor and directing a static charge onto the transfer tube, and an electrostatic discharge system that is configured to transfer a charge generated at a first section of the electrostatic discharge system to a second section of the electrostatic discharge system.

In one aspect, the disclosure provides a power tool comprising a housing, a motor disposed within the housing, an output channel configured to receive a tool bit driven by the motor for performing a working operation, a transfer tube at least partially disposed within the housing, a fan driven by the motor and directing a static charge onto the transfer tube, a printed circuit board disposed within the housing, and a static discharge mechanism extending from an interior of the housing to an exterior of the housing that is configured to prevent electronic charge from building up on the printed circuit board.

In some examples, the power tool includes a conductor that extends between the transfer tube and the handle and the conductor is exposed at the handle. In some examples, the conductor includes a first conductor that is coupled to the handle, a second conductor that is coupled to the transfer tube, and a third conductor that extends between the first conductor and the second conductor. In some examples, the third conductor is a wire that extends into at least one of the handle and the drive unit housing, and extends adjacent to one of a printed circuit board a motor, and a battery receptacle. In some examples, the first conductor is a wire having a first portion coupled to an interior of the handle and a second portion coupled to an exterior of the handle. In some examples, the second conductor is a metal plate that is shaped to follow an outer contour of the transfer tube. In some examples, the power tool further includes an impact mechanism configured to be driven by an output shaft of the motor, and wherein the impact mechanism is configured to apply axial impacts to the tool bit such that the working operation includes a hammering operation. In some examples, the fan is mounted to an output shaft of the motor, and the transfer tube has an opening adjacent the output chuck. In some examples, the transfer tube is disposed within the drive unit housing portion, and the power tool further includes a dust box that is removably coupled to the drive unit housing portion for storing dust and debris passing through the transfer tube.

In some examples, the electrostatic discharge system further includes a wire, and the wire extends between the first section of the electrostatic discharge system and the second section of the electrostatic discharge system. In some examples, the transfer tube extends between the output portion and the second housing. In some examples, the power tool further includes a dust box housing within the second housing, and the fan is mounted between the motor and the dust box housing. In some examples, the electrostatic discharge system includes a metal wire that extends between a first housing portion and a second housing portion. In some examples, the electrostatic discharge system further includes a first conductor and a second conductor. In some examples, a first end of the wire is electrically connected to the first conductor, and a second end of the wire is electrically connected to the second conductor. In some examples, the power tool further includes a printed circuit board disposed within the housing. In some examples, the fan includes a first set of blades that is configured to generate a first air flow that cools the printed circuit board, and a second set of blades that is configured to generate a second air flow that induces air flow through the housing. In some examples, the power tool further includes a battery receptacle comprising an outer surface and one or more battery terminals. In some examples, the one or more battery terminals are disposed on the outer surface of the battery receptacle.

In some examples, the transfer tube is disposed within the housing, and the power tool further includes a dust box that is removably coupled to the housing for storing dust and debris passing through the transfer tube. In some examples, the static discharge mechanism includes a wire, and the wire includes a first portion, a second portion, and a third portion. In some examples, the first portion and the third portion of the wire are disposed within the housing. In some examples, the second portion extends between an inside of a handle portion of the housing to an outer surface of the handle portion of the housing. In some examples, the second portion of the wire extends along the outer surface of the handle portion of the housing from a first end to a second end, such that the first end is proximate to a battery receptacle of the power tool and a second end is proximate to a transmission housing of the power tool. In some examples, the second portion of the wire extends along the outer surface of the handle portion of the housing, such that the second portion of the wire extends in a direction that is substantially parallel to a longitudinal direction of the handle portion. In some embodiments, the transfer tube is configured to move between an extended state and a contracted state.

According to one aspect of the present disclosure, a power tool includes a housing including a handle and a drive unit housing. A motor can be disposed within the drive unit housing. An output chuck ca be configured to receive a tool bit driven by the motor for performing a working operation. A transfer tube can be at least partially disposed within the housing. A fan can be driven by the motor to induce an airflow for transporting dust and debris generated during the working operation through the transfer tube. A conductor can beat least partially exposed along an exterior side of the housing to transmit a static charge that is generated by the fan on the transfer tube during the working operation.

In some examples, the transfer tube can be within the drive unit housing and the conductor can extend between the transfer tube and the handle. The conductor can be exposed at the handle. The conductor can include a first conductor that is coupled to the handle, a second conductor that is coupled to the transfer tube, and a third conductor that extends between the first conductor and the second conductor. The third conductor can be a wire that extends into at least one of the handle, the drive unit housing, and a battery receptacle. The first conductor can be a wire having a first portion coupled to an interior of the handle and a second portion coupled to an exterior of the handle. The second conductor can be a metal plate that is shaped to follow an outer contour of the transfer tube.

In some examples, the power tool can further include an impact mechanism configured to be driven by an output shaft of the motor to apply axial impacts to the tool bit, so that the working operation includes a hammering operation. The fan can be mounted to an output shaft of the motor, and wherein the transfer tube has an opening adjacent the output chuck. The transfer tube can be disposed within the drive unit housing. In some cases, the power tool can further include a dust box that is removably coupled to the drive unit housing for storing dust and debris passing through the transfer tube.

According to another aspect of the present disclosure, a power tool can include a housing assembly, a motor disposed within the housing assembly to power a working operation with a tool bit, a transfer tube at disposed within the housing assembly, and a fan arranged within the housing assembly to induce a static charge onto the transfer tube. An electrostatic discharge system can be in electrical communication with the transfer tube at a first section of the electrostatic discharge system, and is configured to transfer a charge generated at the first section to a second section of the electrostatic discharge system to an exterior of the housing assembly.

In some examples, the electrostatic discharge system can include a wire that extends within the housing assembly between the first section of the electrostatic discharge system and the second section of the electrostatic discharge system to electrically connect the first and second sections of the electrostatic discharge system. The power tool can further include an output portion configured to receive the tool bit and the motor can be disposed within a drive unit housing spaced apart from the output portion. The transfer tube can extend between the output portion and the drive unit housing. The power tool can further include a dust box housing and the fan can be mounted between the motor and the dust box housing.

In some examples, the transfer tube can be within a first housing section of the housing assembly and the housing assembly can further include a second housing section. The electrostatic discharge system can include a wire that extends between the first housing and the second housing. The electrostatic discharge system can further include a first conductor and a second conductor. A first end of the wire can be electrically connected to the first conductor within a first housing of the housing assembly and a second end of the wire can be electrically connected to the second conductor within a second housing of the housing assembly.

In some examples, the power tool can further include a printed circuit board disposed within the housing assembly. The fan can include a first set of blades arranged to generate a first air flow that cools the printed circuit board and a second set of blades arranged to generate a second air flow that transfers dust through the transfer tube. The power tool can further include a battery receptacle comprising an outer surface and one or more battery terminals. The one or more battery terminals can be disposed on the outer surface of the battery receptacle.

According to yet another aspect of the present disclosure, a power tool can include a housing, a motor disposed within the housing, and a transfer tube at least partially disposed within the housing. A fan can be is driven by the motor to cause dust to move along the transfer tube. A printed circuit board can be disposed within the housing and configured to control operation of the motor. An electrostatic discharge mechanism can extend within an interior of the housing that is configured to dissipate electrostatic charge from the transfer tube away from the printed circuit board.

In some examples, the transfer tube can be disposed fully within the housing. The power tool can further include a dust box that is removably coupled to the housing for storing dust and debris received through the transfer tube. The electrostatic discharge mechanism can include a wire that extends between an inside of a handle portion of the housing to an outer surface of the handle portion of the housing.

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting.

### BRIEF DESCRIPTION OF THE DRAWINGS

The accompanying drawings, which are incorporated in and form a part of this specification, illustrate embodiments of the invention and, together with the description, serve to explain the principles of embodiments of the invention.

FIG. 1A is a first side perspective view of a power tool including a dust collection assembly according to an embodiment of the disclosure.

FIG. 1B is a second side perspective view of the power tool of FIG. 1A.

FIG. 2 is a cross-sectional view of the power tool of FIG. 1A taken along line 2-2.

FIG. 3 is a plan view of a portion of the power tool of FIG. 1A.

FIG. 4 is a perspective view of another portion of the power tool of FIG. 1A.

FIG. 5A is a top perspective view of the power tool of FIG. 1A with a depth setting mechanism in a first position.

FIG. 5B is a top perspective view of the power tool of FIG. 1A with the depth setting mechanism in a second position.

FIG. 6 is a plan view of a portion the power tool of FIG. 1A.

FIG. 7 is a perspective view of a portion of a handle housing for the power tool of FIG. 1A.

FIG. 8 is a perspective view of a portion of a drive unit housing for the power tool of FIG. 1A.

### DETAILED DESCRIPTION

Disclosed embodiments will now be described more fully hereinafter with reference to the accompanying drawings, in which some, but not all of the disclosed embodiments are shown. Indeed, several different embodiments may be provided and should not be construed as limited to the embodiments set forth herein. Rather, these embodiments are provided so that this disclosure will be thorough and complete and will fully convey the scope of the disclosure to those skilled in the art.

As used herein, “about”, “approximately,” “substantially,” and “significantly” will be understood by persons of ordinary skill in the art and will vary to some extent on the context in which they are used. If there are uses of the term which are not clear to persons of ordinary skill in the art given the context in which it is used, “about” and “approximately” will mean plus or minus <10% of the particular term and “substantially” and “significantly” will mean plus or minus >10% of the particular term.

As also used herein, unless otherwise defined or limited, ordinal numbers are used herein for convenience of reference based generally on the order in which particular components are presented for the relevant part of the disclosure. In this regard, for example, designations such as “first,” “second,” etc., generally indicate only the order in which the relevant component is introduced for discussion and generally do not indicate or require a particular spatial arrangement, functional or structural primacy or order.

The disclosed power tool will be described with respect to an example rotary hammer. However, it should be understood that any one or more example embodiments of the disclosed rotary hammer can be incorporated in alternate forms of a power tool, for example, hammer drills, hammer chisel, demolition hammers, etc. Furthermore, it should be understood that one or more example embodiments of the disclosed power tool can be used outside of the context of a rotary hammer and could more generally be used in a mechanism that imparts both rotational motion and axial impacts to a tool bit.

According to aspects of the disclosure a power tool can include a dust extraction system that is coupled to a housing of the power tool to suction dust and debris results during a power tool operation (e.g., drilling, chiseling, etc.). The dust extraction system creates suction via a fan that is operatively coupled to a motor to suction dust away from a work surface and transport the dust to a container for collection. Correspondingly, the dust extraction system can include tubing or the like to transfer the dust away from the work surface to the container. As the dust travels along the tube an electrostatic charge (e.g., a static charge) can build on the tubing, where it can spread to the entire tool. In particular, the static charge can migrate to printed circuit boards, sensors, and other sensitive electronic components.

To provide protection against static charge buildup, the power tool can include an electrostatic dissipation system (e.g., a discharge system or a grounding system) that prevents build-up of static charge on the power tool. The discharge system is configured to electrically ground the tool to dissipate any static charge to a grounding body (e.g., a charge sink such as earth, a work surface, a support structure, an operator, etc.). In general, the discharge system can include one or more conductors that are coupled between one or more components of the dust extraction system (e.g., tubing, dust container, etc.) and a terminal positioned external to the housing to contact the grounding body. As one particular example, a discharge system can include a first conductor that is coupled to the tube, a second conductor that is coupled to a handle of the power tool, and a third conductor that is coupled between the first conductor and the second conductor. At least a portion of the second conductor is disposed on an exterior of the handle (e.g., an exterior of the housing) to define a terminal of the discharge system. The third conductor can be a flexible wire that is configured to contact other components of the power tool (e.g., a housing, gearbox, etc.). When a grounding body (e.g., a hand of an operator) contacts the terminal, static charge that builds on the power tool can flow from the first conductor, along the third conductor, to the second conductor where it is discharged to the grounding body. It is appreciated that one or more of the first conductor, the second conductor, and the third conductor can be sections of the same conductor or can be different conductors that can be coupled together. Correspondingly, more or fewer conductors can be used.

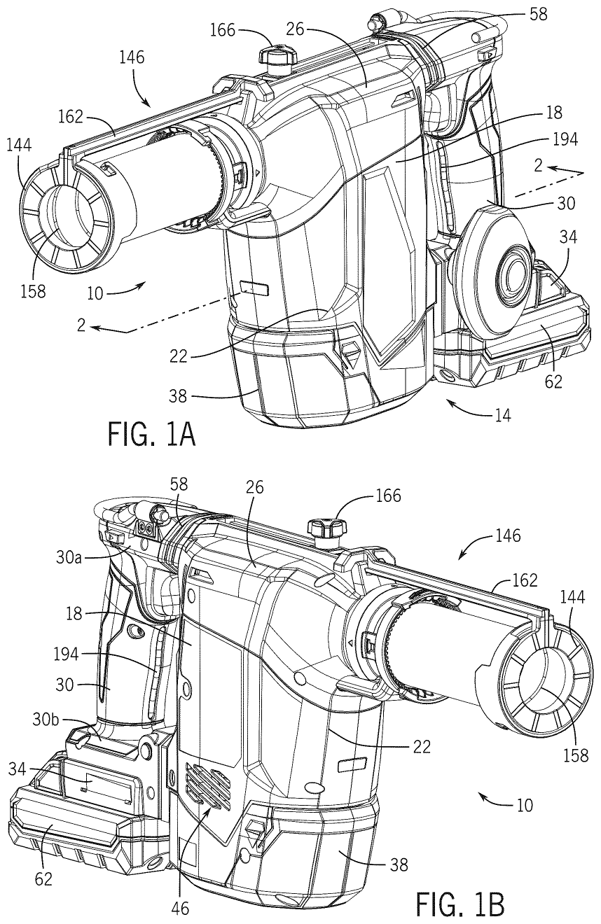

FIGS. 1A and 1B illustrate a power tool 10. In the illustrated embodiment, the power tool 10 is a rotary hammer. The power tool 10 includes a dust collection assembly 14 integrated within the body of the tool. In other embodiments, one or more portions of the dust collection assembly 14 may be realized as a separate element from the power tool 10 or may be positioned externally of the power tool 10. As will be appreciated, integration of the dust collection assembly 14 within the power tool 10 may allow for a reduced number of parts for the operation of the power tool 10 and the dust collection assembly 14. For example, in some embodiments, the dust collection assembly 14 and the power tool 10 may share certain parts. As such, integration may reduce the overall size, weight, and cost of the tool system. The profile of the tool system is also more compact, thereby allowing a user to maneuver and hold the tool system more easily. It is understood that the various features and embodiments described in the present disclosure may be mixed or interchanged into different combinations of features and embodiments. In other words, the specific combinations of features disclosed herein are not intended to be limiting but are purely for the sake of illustrating example embodiments.

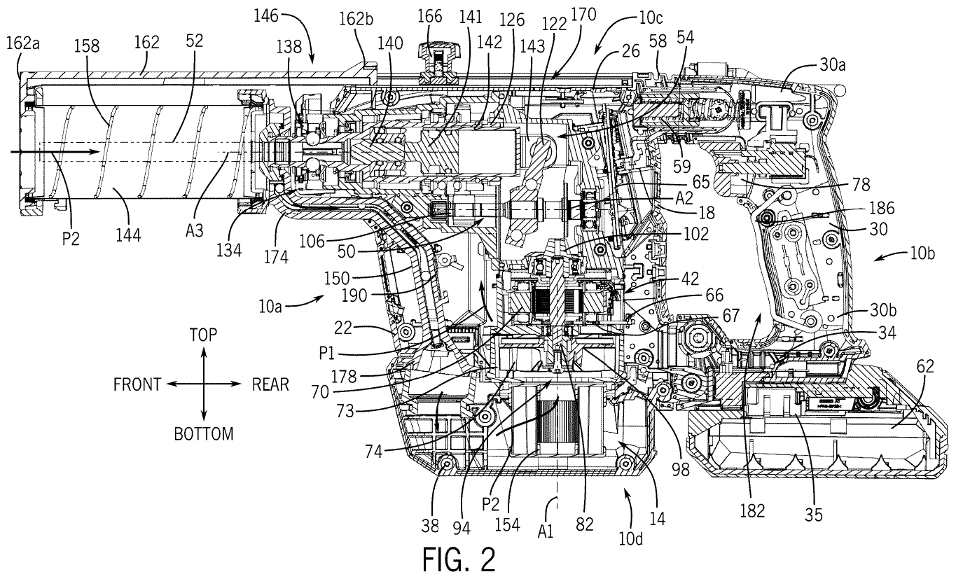

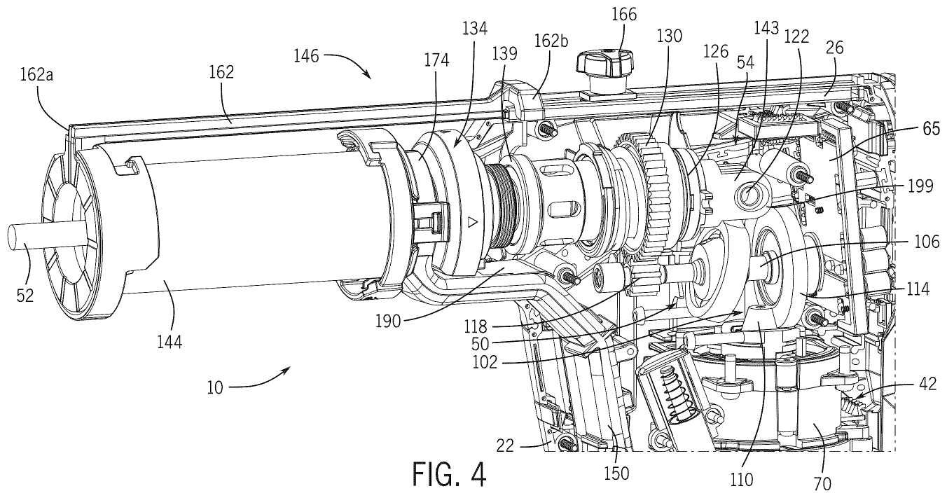

The power tool 10 includes a housing 18 configured to house operating components of the power tool 10 therein. The housing 18 can define different sections or regions, which may be part of separate housings that are coupled to form the housing 18 as a housing assembly, or that are formed together as a unitary housing. For the purposes of this discussion, a unitary housing can include housings with a clamshell type construction that form one or more sections of the housing, with each half of the clamshell being a monolithic component. The various housing sections can correspond with a component being received therein or as forming a particular structure of the power tool 10. For example, the housing 18 includes a drive unit housing 22, a transmission housing 26, a handle housing 30, a battery receptacle 34, and a dust box housing 38. In some examples drive unit housing 22, the transmission housing 26, the handle housing 30, the battery receptacle 34, and the dust box housing 38 can be considered housing sections of a unitary housing. With reference to FIGS. 1B and 2, the drive unit housing 22 houses a drive unit 42 that is configured to produce, or generate, torque. The drive unit housing 22 defines a vent 46 that allows air to flow into and out of the housing 18. In some embodiments, the drive unit housing 22 is formed of clamshell halves that may be coupled together (e.g., via fasteners, a snap-fit connection, etc.). The transmission housing 26 houses a transmission 50 (e.g., a transmission assembly), which is configured to receive torque from the drive unit 42 and rotationally drive a tool bit 52 (FIG. 4), and an impact mechanism 54, which is configured to receive torque from the transmission 50 and apply impacts to the tool bit 52 (FIG. 4). The handle housing 30 is configured to be grasped by a user for control and operation of the power tool 10.

In some implementations, the technology disclosed herein can be particularly beneficially used with the impact mechanism 54 as configured in the illustrated example. In other examples, however, other impact mechanisms can be used, including other arrangements known in the art to convert torque received from a motor into impacts on (or with) a tool bit.

In some examples, the handle housing 30 can be a separate component that is movably coupled to the rest of the housing 18, which can be integrally formed with one another (e.g., in a clamshell construction). The handle can move to minimize vibration transmission to an operator. For example, in the illustrated embodiment, the handle housing 30 is moveably coupled to the transmission housing 26 at a first end 30a of the handle housing 30 via an elastic member 58. The elastic member 58 is configured to allow for movement of the handle housing 30 relative to the transmission housing 26 while also sealing the handle housing 30 from contaminants. In some embodiments, the clastic member 58 is replaced by a different vibration absorbing member. In some embodiments, the elastic member 58 is used in conjunction with another damping member, such as, for example, a spring or clastic bushing, or another type of damping element, such as a dashpot, shock absorber, etc. In the illustrated embodiment, a spring 59 is disposed in an internal cavity formed between the handle housing 30 and the transmission housing 26. The spring 59 is configured to absorb and/or dampen vibration between the transmission housing 26 and the handle housing 30 by moving between an extended state and a compressed state. To that end, the elastic member 58 is configured to move between an extended state and a compressed state as the spring 59 moves between an extended state and a compressed state. In some embodiments, multiple damping members, such as, for example, multiple springs, are included. In some embodiments, the damping members are placed differently with respect to the transmission housing 26 and the handle housing 30. In some embodiments, no vibration absorbing members are included. In some embodiments, the damping member(s) may be an elastic bushing, a dashpot, a shock absorber, and the like.

The battery receptacle 34 is positioned at a second end 30b of the handle housing 30 opposite from the first end 30a. In the illustrated embodiment, the battery receptacle 34 is integrally formed with the drive unit housing 22 and the handle housing 30. As mentioned above, in some embodiments, the battery receptacle 34 is realized as a separate component from one or both of the drive unit housing 22 and the handle housing 30. In some embodiments, each of the drive unit housing 22, the handle housing 30, and the battery receptacle 34 includes clamshell halves that are coupled together via fasteners. In some embodiments, the drive unit housing 22, the handle housing 30, and/or the battery receptacle 34 are unitary bodies. The battery receptacle 34 is configured to receive a battery 62 that provides power to the drive unit 42 for producing, or generating, torque. The dust box housing 38 is positioned adjacent to the drive unit housing 22 and is configured to store dust and debris collected by the dust collection assembly 14. The dust box housing 38 is positioned between the drive unit housing 22 and the battery receptacle 34.

With reference to the orientation of the power tool 10 in FIG. 2, the power tool 10 has a front or forward end 10a, a rear or rearward end 10b, a top or upper-most end 10c, and a bottom or bottom-most end 10d. As such, the drive unit housing 22 is positioned at the forward end 10a of the power tool 10 and positioned between the transmission housing 26 and the dust box housing 38 (e.g., in a top-to-bottom direction). The transmission housing 26 is positioned above the drive unit housing 22 at a forward and upper-most section of the power tool 10. The transmission housing 26 extends between the drive unit housing 22 and the handle housing 30. The handle housing 30 is positioned behind the transmission housing 26 and above the battery receptacle 34 (e.g., at a rearward and upper-most section of the power tool 10). The battery receptacle 34 is positioned below the handle housing 30 at a rearward and bottom section of the power tool 10. The battery receptacle 34 extends between the handle housing 30 and the dust box housing 38. In some embodiments, the battery receptacle 34 extends between the handle housing 30 and the drive unit housing 22. In some embodiments, the battery receptacle 34 includes a battery terminal 35 or a plurality of battery terminals that are located on an exterior side of the battery receptacle 34. The battery terminal 35 provides an electrical connection to the battery 62 when the battery 62 is received in the battery receptacle 34. The dust box housing 38 is positioned below the drive unit housing 22 at a forward and bottom section of the power tool 10. In some embodiments, the dust box housing 38 extends between the drive box housing 38 and the battery receptacle 34. In some embodiments, the dust box housing 38 is only coupled to the drive unit housing 22. The following disclosure includes reference to directional locations such as forward, rearward, top, and bottom locations. As such, any reference made to directional location is made with respect to the directional signifier indicated in FIG. 2.

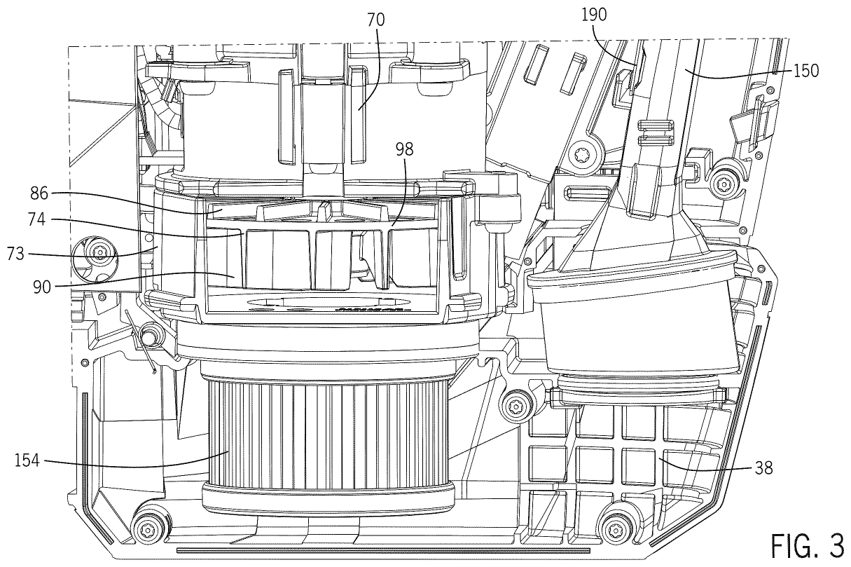

In some examples, a power tool can include one or more printed circuit board assemblies (“PCB”) to control operation of the power tool. For example, with reference to FIGS. 2 and 3, the drive unit 42 includes first PCB 65 and a second PCB 66. The first PCB 65 is disposed in the drive unit housing 22 and is configured to control operation of a motor 70 based on an input from a user (e.g., operation of the trigger 78). The PCB 65 can function as an electronic controller to control an electrical current that is supplied from the battery 62 to the motor 70. The second PCB 66 is positioned within the drive unit housing 22 adjacent to the battery receptacle 34. The second PCB 66 is configured as a sensor board that includes one or more sensors to detect an operating parameter of the motor 70. In the illustrated example, the second PCB 66 includes a plurality of hall sensors 67 that are in communication with the first PCB 65 and that are configured to detect a rotational position of the motor 70. In other examples, other types of sensors can be used, for example, speed sensors, torque sensors, etc. that can be used to detect other operating parameters of the motor 70. In some embodiments, the PCB 66 is located between a fan shroud 73 and the motor 70.

The motor 70 is a brushless direct current (“BLDC”) motor and is configured to rotate under control of the PCB 66 in response to user input, such as actuation of a trigger 78. In some embodiments, the motor 70 is another type of direct current (DC) motor, alternating (AC) motor, or any other motor type. The motor 70 includes an output shaft 82 that is rotatable about a drive axis A1. A fan 74, can be mounted to the output shaft 82 at a bottom-most end of the output shaft 82 (e.g., an end of the output shaft 82 that is closest to a body of the motor 70 and farthest from the transmission housing 26). The fan shroud 73 surrounds the fan 74 and can help to isolate any dust and debris moved by the fan 74 from the rest of the power tool 10 by directing the dust or debris to the dust box housing 38. The fan 74 includes a first set of blades 86 and a second set of blades 90. The first set of blades 86 is positioned between the motor 70 and the second set of blades 90. The second set of blades 90 is positioned above a suction inlet 94 defined in the drive unit housing 22 (e.g., the second set of blades 90 is positioned between the suction inlet 94 and the transmission housing 26). In the illustrated embodiment, the fan 74 includes a dividing wall 98 that substantially separates the first set of blades 86 and the second set of blades 90. The first set of blades 86 is configured to generate a first flow of air P1 for, among other things, cooling the PCB 66 and the motor 70. The second set of blades 90 is configured to generate a second flow of air P2 for inducing air flow through the dust collection assembly 14, as will be described in further detail. In the illustrated embodiment, the first flow of air P1 and the second flow of air P2 may be kept substantially separate from one another by the dividing wall 98. In other embodiments, the fan 74 may not include a dividing wall 98.

As illustrated in FIGS. 2 and 4, the transmission 50 includes a bevel gear 102 and an intermediate shaft 106 that defines a transmission axis A2 extending in a front-to-rear direction (FIG. 2). In some embodiments, the transmission axis A2 is defined along the length of the intermediate shaft 106 between a first end and a second end of the intermediate shaft 106. In some embodiments, a cage and peg gear, a worm gear, a spur gear, or a different gear is used in place of or in conjunction with the bevel gear 102. The transmission axis A2 is substantially perpendicular to the drive axis A1. In some embodiments, the intermediate shaft 106 and the corresponding transmission axis A2 are at an acute angle relative to the drive axis A1. The bevel gear 102 includes a bevel input gear 110 and a bevel output gear 114. The bevel input gear 110 is mounted to the output shaft 82 of the drive unit 42 for rotation with the output shaft 82 about the drive axis A1. The bevel output gear 114 is supported by the housing 18 and is oriented substantially perpendicular to the bevel input gear 110 for converting rotation about the drive axis A1 from the drive unit 42 to rotation about the transmission axis A2. The intermediate shaft 106 is also supported by the housing 18 and extends through the bevel output gear 114 such that the intermediate shaft 106 is configured to rotate with the bevel output gear 114. The intermediate shaft 106 includes at least one pinion gear 118 at an end of the intermediate shaft 106 opposite from the bevel output gear 114.

The impact mechanism 54 includes a hammer 122 and a spindle 126 that defines an impact axis A3 extending in a front-to-rear direction. The spindle In some embodiments, the impact axis A3 is substantially perpendicular (e.g., to be within about 15 degrees of perpendicular) to the drive axis A1 and is substantially parallel to the transmission axis A2. In other embodiments, the impact axis A3 may be oriented differently, for example, so that the impact axis A3 is substantially parallel (e.g., to be within about 15 degrees of parallel) to the drive axis A1 and substantially perpendicular to the transmission axis A2. The hammer 122 is reciprocated by the motor 70 (via the transmission 50) to impart axial impacts to the tool bit 52. The hammer 122 is coupled to the intermediate shaft 106 of the transmission 50 such that rotation of the intermediate shaft 106 effects the hammer 122 spindle to oscillate at periodic intervals (e.g., to generate reciprocating linear motion). Specifically, the hammer 122 reciprocates a direction extending along the impact axis A3. The spindle 126 is rotated by the motor 70 (via the transmission 50) to cause rotation of a tool bit. The spindle 126 includes a drive gear 130 coupled thereto that is meshed with the pinion gear 118 of the intermediate shaft 106 such that the intermediate shaft 106 is configured to drive rotation of the spindle 126 via the engagement between the pinion gear 118 on the intermediate shaft 106 and the anvil gear 130 on the spindle 126.

With continued reference to FIGS. 2 and 4, the power tool 10 includes an output chuck 134 that extends through the transmission housing 26 at the forward end 10a of the power tool 10. The output chuck 134 is configured to receive the tool bit 52. In the illustrated embodiment, the output chuck 134 includes a ball detent mechanism 138 for retaining the tool bit 52. In some embodiments, other retention mechanisms, such as a keyless chuck, a keyed chuck, and/or a hybrid chuck, are used in place of or in conjunction with the output chuck 134 including the ball detent mechanism 138. When the tool bit 52 is received in the output chuck 134, the tool bit 52 extends along and is configured to rotate about the impact axis A3. As such, the impact axis A3 may also be referred to as an output axis A3. In other embodiments, the output chuck 134 may include different features for retaining a tool bit 52. The output chuck 134 is engaged with the spindle 126 such that rotation from the transmission 50 and axial impacts from the impact mechanism 54 may be transferred to the tool bit 52 when the tool bit 52 is coupled to the output chuck 134. As such, the drive unit 42 is configured to rotationally drive the tool bit 52 through the transmission 50 and the spindle 126 for performing a drilling operation, and is configured to produce axial impacts on the tool bit 52 through the transmission 50 and the impact mechanism 54 for performing a hammering operation. In some embodiments, the power tool 10 includes a mode selection actuator that is engaged with the transmission 50 and the impact mechanism 54 for placing the power tool 10 in a hammer-only mode, a drilling-only mode, or a hammer and drilling mode.

With reference to FIGS. 2 and 4, in some embodiments, a spindle 126 is disposed within the output chuck 134 and between the tool bit 52 and the spindle 126. In some embodiments, the transmission 50 transmits torque from the motor 70 to the spindle 126, causing the spindle 126 to rotate when the motor 70 is activated. Disposed within the spindle is an anvil 140 that is disposed between a distal end of the spindle 126 and the spindle 126. In some embodiments, a distal end of the anvil 140 that is disposed closest to the tool bit 52 is used as a striking face to produce axial impacts on the tool bit 52. The transmission housing 26 (e.g., a gearbox) may further include a striker 141, a piston 142, and a yoke 143. In some embodiments, the hammer 122 drives the piston 142 to reciprocate in response to rotation of the intermediate shaft 106.

FIGS. 2 and 4 illustrate the impact mechanism 54 of the power tool 10. The impact mechanism 54 is configured to impart repeated axial impacts to a tool bit 52. The impact mechanism 54 can generate impact energy via an oscillation mechanism (e.g., the hammer 122) that converts the rotational motion of the motor 70 into reciprocating linear motion. The impact mechanism (e.g., the oscillation mechanism) can be driven by the motor 70. In some cases, the impact mechanism can be driven by (e.g., receive an input from) the transmission 50, or it can be driven by a separate drive system. The impact mechanism can include an oscillating mechanism that is configured to convert rotational motion of the motor 70 into reciprocating linear motion that is used to deliver repeated (axial) impacts to the tool bit 52. The oscillation mechanism can be configured as, for example, a cam-follower, crank-slider, swashplate, or another type of system configured to generate reciprocating linear movement from a rotational input. In this case, the hammer 122 is part of a wobble bearing assembly that causes the rotational motion of the intermediate shaft 106 to generate reciprocating motion of the hammer 122 that causes the piston 142 to reciprocate within the spindle 126. More specifically, wobbling movement of the hammer 122 is transmitted to reciprocation motion to the piston 142 to drive the piston 142 to reciprocate. For example, the hammer 122 is movably coupled to the yoke 143 that drives the linear reciprocating motion of the piston 142. In some embodiments, the yoke 143 is disposed between the hammer 122 and the piston 142. In some embodiments, the piston 142 is disposed between the yoke 143 and the striker 141. In some embodiments, the striker 141 is disposed between the anvil 140 and a distal end of the piston 142 that is closest to the yoke 143. In some embodiments, the anvil 140 is disposed between the striker 141 and the tool bit 52.

With continued reference to FIG. 2, the piston 142 is hollow and defines an interior chamber in which the striker 141 is movably received. An air spring is developed between the piston 142 and the striker 141. When the piston 142 reciprocates within the spindle 126, the piston 142 and the striker 141 can move relative to one another. For example, as the piston 142 is moved toward the anvil 140, the air pocket is compressed, and as the piston 142 is moved away from the anvil 140, the air pocket is expanded. This expansion and retraction of the air pocket results in pressure changes in the air pocket that cause reciprocation of the striker 141.

With additional reference to FIGS. 2 and 4, the anvil 140 is configured to impart axial impacts onto the tool bit 52 in response to the reciprocation of the piston 142 and the striker 141.

In operation, when the tool bit 52 is attached to the output chuck 134 and depressed against a workpiece, the tool bit 52 pushes the striker 141 (via the anvil 140) toward the piston 142 to attain an “impact” position of the striker 141. During operation of the power tool 10, the piston 142 reciprocates within the spindle 126 to draw the striker 141 away from the anvil 140 and then accelerate it towards the anvil 140 for impact.

As illustrated in FIG. 2, the dust collection assembly 14 includes a dust tube 144, a depth setting mechanism 146, a dust transfer tube 150, and a filter 154. The dust collection assembly 14 is configured to perform a suctioning operation during the drilling and/or hammering operation. Specifically, dust and debris may be generated during the drilling and/or hammering operation, and the dust collection assembly 14 is configured to suction the dust and debris away from a work surface and into the dust box housing 38, as will be described in more detail.

The dust tube 144 extends from the output chuck 134 such that the tool bit 52 (FIG. 4) may extend through the dust tube 144. In the illustrated embodiment, the dust tube 144 is formed of a flexible material, such as a fabric (e.g., nylon) or flexible plastic that is compressible to move between an extended state and a collapsed state. In some examples, a biasing element can be provided to bias the dust tube 144 away from the output chuck 134 in the extended state. In the illustrated example, a biasing element is configured as a spring 158 and is positioned within the dust tube 144 and biases the dust tube 144 away from the output chuck 134 in the extended state. During the drilling and/or the hammering operation, the spring 158, and therefore the dust tube 144, may be compressed against a work surface to move the dust tube 144 toward the collapsed state. In other embodiments, the dust tube 144 may be a rigid tube or a telescoping tube.

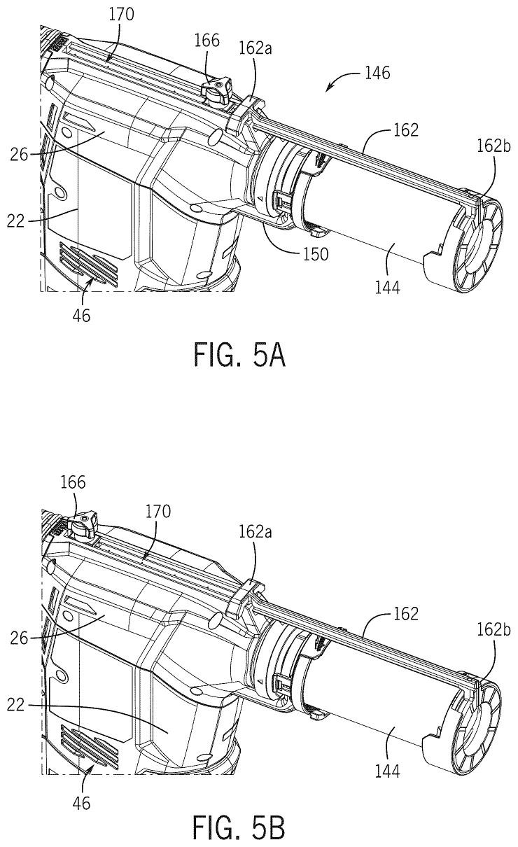

With reference to FIGS. 2, 5A, and 5B, the depth setting mechanism 146 includes a guide rail 162 and an adjustment knob 166. The guide rail 162 has a first end 162a positioned at the transmission housing 26 and a second end 162b positioned at a forward-most end of the dust tube 144. The guide rail 162 is configured to slide along a groove 170 formed in the transmission housing 26 as the dust tube 144 moves between the extended state and the collapsed state. The adjustment knob 166 is positioned in the groove 170 and is configured to set the insertion depth for the tool bit 52 (FIG. 4) of the power tool 10 into a work surface. That is, as the dust tube 144 moves between the extended state and the collapsed state, the first end 162a of the guide rail 162 may move rearwardly until the first end 162a of the guide rail 162 hits, or engages, the adjustment knob 166 such that the adjustment knob 166 inhibits further rearward movement of the guide rail 162 (e.g., away from the extended state). As such, if a relatively small bore hole is desired, the adjustment knob 166 may be placed adjacent to the first end 162a of the guide rail 162 (e.g., as illustrated in FIG. 5A) such that rearward movement of the guide rail 162 is inhibited shortly after the tool bit 52 (FIG. 4) is inserted into a work surface. If a relatively larger bore hole is desired, the adjustment knob 166 may be moved along the groove 170 to a position further away from the first end 162a of the guide rail 162 (e.g., as illustrated in FIG. 5B) such that the dust tube 144 is able to move to the collapsed state before the first end 162a of the guide rail 162 reaches the adjustment knob 166.

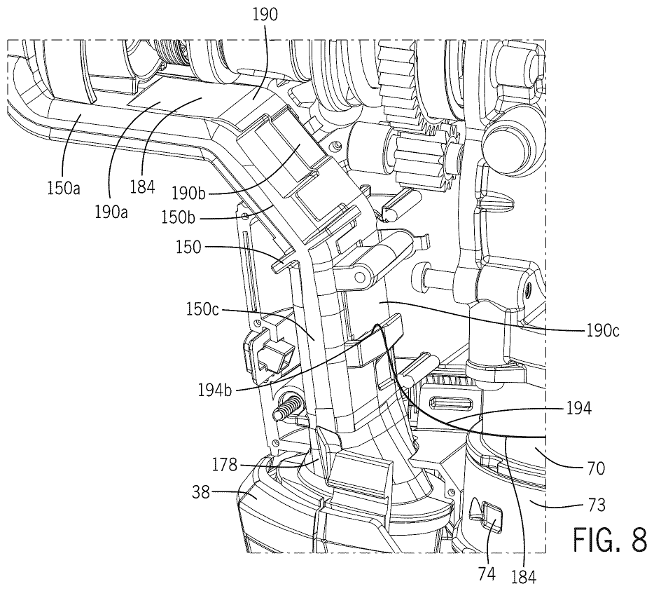

With reference to FIG. 2, the dust transfer tube 150 includes an inlet 174 and an outlet 178. The inlet 174 defines an opening adjacent to the output chuck 134. Specifically, the inlet 174 is positioned substantially between the output chuck 134 and the dust tube 144. In the illustrated embodiment, the inlet 174 surrounds a portion of the output chuck 134 such that the tool bit 52 (FIG. 4) is configured to extend at least partially through the inlet 174 of the dust transfer tube 150. The outlet 178 is positioned at an interface between the drive unit housing 22 and the dust box housing 38. As such, the dust transfer tube 150 defines a pathway between the inlet 174 and the outlet 178 for airflow, including dust and debris, to travel from the dust tube 144 to the dust box housing 38. In the illustrated embodiment, with reference to FIGS. 2 and 8, the dust transfer tube 150 has an outer profile defined by a first portion 150a that extends in a rearward direction (e.g., toward the handle housing 30), a second portion 150b that extends in a rearward and downward (e.g., diagonal) direction (e.g., toward the handle housing 30 and dust box housing 38), and a third portion 150c that extends in a downward direction (e.g., toward the dust box housing 38).

As illustrated in FIG. 2, the filter 154 is positioned below or at the suction inlet 94 in the drive unit housing 22. As such, the filter 154 is positioned below the second set of blades 90 such that the second set of blades 90 induces the second flow of air P2 into the dust tube 144, through the dust transfer tube 150 to the dust box housing 38, through the filter 154, and out of the vent 46 (FIG. 1B) defined in the drive unit housing 22. As the second flow of air P2 passes through the filter 154, dust and debris is separated from the second flow of air P2. The separated dust and debris may then be stored in the dust box housing 38 until the dust box housing 38 is cleaned out. Specifically, the dust box housing 38 may be removably coupled to the drive unit housing 22 such that the dust box housing 38 is removable to clean dust and debris from the dust box housing 38.

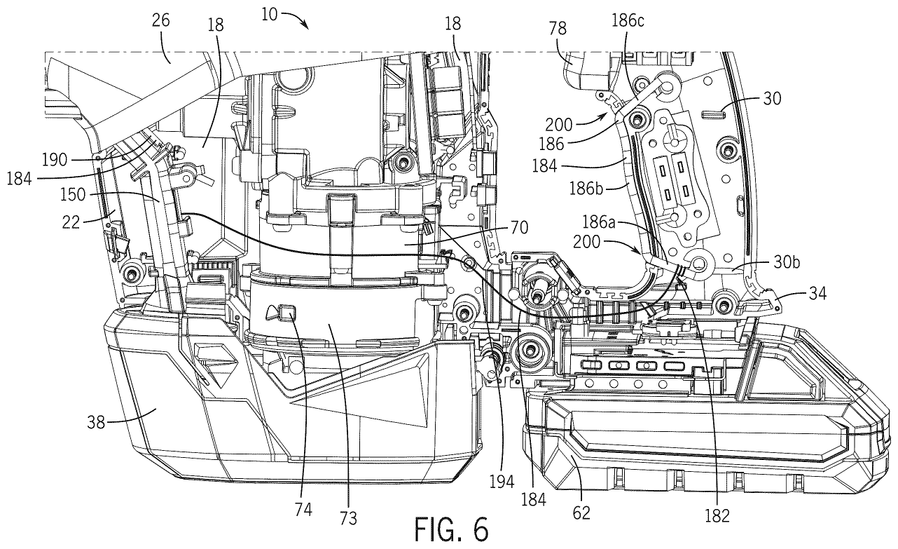

In some examples, the handle housing 30 includes an electrostatic discharge mechanism (e.g., a conductor) that is configured to collect and contain static discharge until it is grounded. In some embodiments, the component is configured to be contacted by a user, such that contact with the user grounds the static discharge. In some embodiments, the electrostatic discharge mechanism is configured to ground the static discharge using a grounding port, a cable, or another form of transferring or dissipating the static discharge. With reference to FIGS. 6-8, in the illustrated embodiment, the power tool 10 further includes an electrostatic discharge system 182 positioned in the housing 18 of the power tool 10. Specifically, the electrostatic discharge system 182 includes a conductor 184 that includes a first conductor 186 that is positioned in the handle housing 30, a second conductor 190 that is positioned in the drive unit housing 22, and a third conductor 194 (e.g., a wire) that extends between the first conductor 186 and the second conductor 190. In the illustrated example, the wire 194 can be a flexible or rigid, elongate conductor, for example, a braided or solid core wire, bus bar, or another type of conductor as known in the art. The first conductor 186 is configured to dissipate static charge to a user when the user's hand grasps the handle housing 30, the second conductor 190 is configured to localize, or centralize, static charges generated during the drilling and/or hammering operation and suctioned through the dust transfer tube 150, and the wire 194 extends between the first conductor 186 and the second conductor 190 to transmit static charge from the second conductor 190 to the first conductor 186. Specifically, a first end 194a of the wire 194 is electrically connected to the first conductor 186, and a second end 194b of the wire is electrically connected to the second conductor 190. In some embodiments, the wire 194 is replaced by or used in conjunction with a different conductor, such as, for example, a sheet of metal, a rod, conductive polymers (e.g., polymers with a conductive additive), or other conductors of the like.

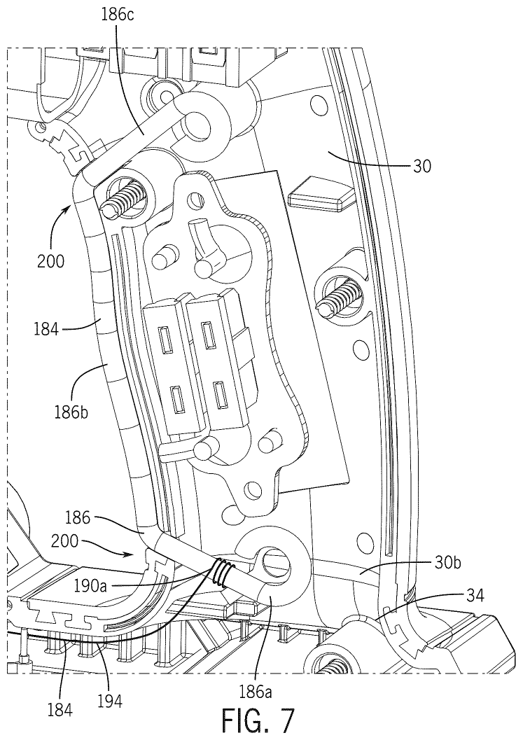

In the illustrated embodiment shown in FIG. 7, the first conductor 186 is a metal wire having a first portion 186a coupled to the housing 18 within an interior of the handle housing 30, a second portion 186b that extends external to the housing 18 from the first portion 186a, and a third portion 186c that extends into the interior of the handle housing 30 from the second portion 186b and is coupled to the housing 18. Each of the first portion 186a and the third portion 186c is coupled to the housing 18 at posts extending from at least one of the clamshell halves of the housing 18. The second portion 186b extends between apertures 200 in the handle housing 30 and extends along an outer surface of the handle housing 30. Specifically, the second portion 186b extends along a forward-most outer surface of the handle housing 30 (e.g., a surface of the handle housing 30 that faces the drive unit housing 22) such that a user's hand grasping the handle housing 30 contacts the first conductor 186. Upon contact between the first conductor 186 and the user's hand, static charges generated during the working operation may be grounded, and therefore, unexpected and undesired shocks may be prevented. In some embodiments, the second portion 186b extends along a rearmost outer surface of the handle housing 30 (e.g., a surface of the handle housing 30 that faces away from the drive unit housing 22), wraps around the handle housing 30, or is otherwise disposed on the outer surface of the handle housing 30 such that the second portion 186b is configured to be contacted by a user's hand or other grounding mechanism during use.

With reference to FIG. 8, the second conductor 190 is a plate that is coupled to the dust transfer tube 150 of the dust collection assembly 14. In some embodiments, the second conductor 190 is a metal plate. The second conductor 190 is shaped to follow the outer contour, or profile, of the dust transfer tube 150. In other words, the second conductor 190 can extend along (e.g., substantially parallel with or seated on) the outer contour of the dust transfer tube 150. As such, the second conductor 190 includes a first portion 190a that extends in a rearward direction (e.g., toward the handle housing 30), a second portion 190b that extends in a rearward and a downward (e.g., diagonal) direction (e.g., toward the handle housing 30 and the dust box housing 38), and a third portion 190c that extends in a downward direction (e.g., toward the dust box housing 38). The second conductor 190 may attract static charge from dust and debris generated during the drilling and/or hammering operation and suctioned through the dust transfer tube 150. The wire 194 then transmits the static charge from the second conductor 190 to the first conductor 186. In the illustrated embodiment, the wire 194 may extend through the drive unit housing 22 around a periphery of the motor 70 to reach the first conductor 186 in the handle housing 30. In other embodiments, the wire 194 may extend through the drive unit housing 22 around the periphery of the fan shroud 73.

The electrostatic discharge system 182 advantageously prevents the buildup of static charges within and/or on the housing 18 of the power tool 10. In particular, the electrostatic discharge system 182 can direct electrostatic buildup away from the PCB 66 or dissipate electrostatic charge that has built on PBC 66. The electrostatic discharge system 182 can similarly direct electrostatic buildup away from or dissipate electrostatic charge that has built on other electronic components, including the motor 70, the battery 62, sensors of the power tool 10, etc. For example, in absence of the electrostatic discharge system 182, dust and debris may move through the dust transfer tube 150 and carry an electric charge into the power tool 10. Without providing a way for dissipating the static charge, the static charge may migrate to any of the printed circuit boards within the tool 10 or the handle housing 30. As such, once a user grasps the handle housing 30 for operating the power tool 10, the static charge may become grounded through the user's hand, thereby causing the user to feel an unwanted shock. Therefore, the electrostatic discharge system 182 improves the comfort and ease of use of the power tool 10.

Although the disclosure has been described in detail with reference to certain preferred embodiments, variations and modifications exist within the scope and spirit of one or more independent aspects of the disclosure as described. Various features of the present disclosure are set forth in the following claims.

What is claimed is:

1. A power tool comprising:
a housing including a handle and a drive unit housing;
a motor disposed within the drive unit housing;
an output chuck configured to receive a tool bit driven by the motor for performing a working operation;
a transfer tube at least partially disposed within the housing;
a fan driven by the motor to induce an airflow for transporting dust and debris generated during the working operation through the transfer tube; and
a conductor at least partially exposed along an exterior side of the housing to transmit a static charge that is generated by the fan on the transfer tube during the working operation.

2. The power tool of claim 1, wherein the transfer tube is within the drive unit housing and the conductor extends between the transfer tube and the handle, the conductor being exposed at the handle.

3. The power tool of claim 2, wherein the conductor includes a first conductor that is coupled to the handle, a second conductor that is coupled to the transfer tube, and a third conductor that extends between the first conductor and the second conductor.

4. The power tool of claim 3, wherein the third conductor is a wire that extends into at least one of the handle, the drive unit housing, and a battery receptacle.

5. The power tool of claim 3, wherein the first conductor is a wire having a first portion coupled to an interior of the handle and a second portion coupled to an exterior of the handle.

6. The power tool of claim 3, wherein the second conductor is a metal plate that is shaped to follow an outer contour of the transfer tube.

7. The power tool of claim 1, further comprising an impact mechanism configured to be driven by an output shaft of the motor to apply axial impacts to the tool bit, so that the working operation includes a hammering operation.

8. The power tool of claim 1, wherein the fan is mounted to an output shaft of the motor, and wherein the transfer tube has an opening adjacent the output chuck.

9. The power tool of claim 1, wherein the transfer tube is disposed within the drive unit housing, and
wherein the power tool further includes a dust box that is removably coupled to the drive unit housing for storing dust and debris passing through the transfer tube.

10. A power tool comprising:
a housing assembly;
a motor disposed within the housing assembly to power a working operation with a tool bit;
a transfer tube at disposed within the housing assembly;
a fan arranged within the housing assembly to induce a static charge onto the transfer tube; and
an electrostatic discharge system that is in electrical communication with the transfer tube at a first section of the electrostatic discharge system, and is configured to transfer a charge generated at the first section to a second section of the electrostatic discharge system to an exterior of the housing assembly.

11. The power tool of claim 10, wherein the electrostatic discharge system includes a wire that extends within the housing assembly between the first section of the electrostatic discharge system and the second section of the electrostatic discharge system to electrically connect the first and second sections of the electrostatic discharge system.

12. The power tool of claim 10, further comprising:
an output portion configured to receive the tool bit;
wherein the motor is disposed within a drive unit housing spaced apart from the output portion; and
wherein the transfer tube extends between the output portion and the drive unit housing.

13. The power tool of claim 10 further including a dust box housing, wherein the fan is mounted between the motor and the dust box housing.

14. The power tool of claim 10, wherein the transfer tube is within a first housing section of the housing assembly and the housing assembly further includes a second housing section; and
wherein the electrostatic discharge system includes a wire that extends between the first housing and the second housing.

15. The power tool of claim 14, wherein the electrostatic discharge system further includes a first conductor and a second conductor,
wherein a first end of the wire is electrically connected to the first conductor within a first housing of the housing assembly, and
wherein a second end of the wire is electrically connected to the second conductor within a second housing of the housing assembly.

16. The power tool of claim 10 further including a printed circuit board disposed within the housing assembly,
wherein the fan includes a first set of blades arranged to generate a first air flow that cools the printed circuit board, and a second set of blades arranged to generate a second air flow that transfers dust through the transfer tube.

17. The power tool of claim 10 further including a battery receptacle comprising an outer surface and one or more battery terminals, wherein the one or more battery terminals are disposed on the outer surface of the battery receptacle.

18. A power tool comprising:
a housing;
a motor disposed within the housing;
a transfer tube at least partially disposed within the housing;
a fan that is driven by the motor to cause dust to move along the transfer tube; a printed circuit board disposed within the housing and configured to control operation of the motor; and
an electrostatic discharge mechanism extending within an interior of the housing that is configured to dissipate electrostatic charge from the transfer tube away from the printed circuit board.

19. The power tool of claim 18, wherein the transfer tube is disposed fully within the housing, and
wherein the power tool further includes a dust box that is removably coupled to the housing for storing dust and debris received through the transfer tube.

20. The power tool of claim 18, wherein the electrostatic discharge mechanism includes a wire that extends between an inside of a handle portion of the housing to an outer surface of the handle portion of the housing.
